(19) United States
(12) Patent Application Publication
(10) Pub. No.: US 2022/0246788 A1
(43) Pub. Date: Aug. 4, 2022

(54) FILM COATING METHOD AND LIGHT-EMITTING DEVICE

(71) Applicant: Skiileux Electricity Inc., Taoyuan City (TW)

(72) Inventor: Jian-Ging Chen, Taoyuan City (TW)

(73) Assignee: Skiileux Electricity Inc., Taoyuan City (TW)

(21) Appl. No.: 17/537,428

(22) Filed: Nov. 29, 2021

(30) Foreign Application Priority Data
Jan. 29, 2021 (TW) 110103398

(51) Int. Cl. H01L 33/00; H01L 25/075; H01L 33/50

(52) U.S. Cl. CPC H01L 33/005; H01L 2933/0041; H01L 33/504; H01L 25/0753

(57) ABSTRACT

A film coating method includes the following steps of: providing an object to be coated; providing a mask; disposing the mask above the object; disposing a coating material film above the object and the mask; and making the coating material film and the object approach each other so as to make the coating material film form a coating layer on a surface area to be coated of the object through a pattern of the mask. A light-emitting device includes a substrate and a plurality of light-emitting parts separately arranged on an upper surface of the substrate. An optical wavelength conversion layer covers a light-emitting surface of the light-emitting part. The optical wavelength conversion layer is a compact powder layer and touches the upper surface. The upper surface has a clearance area without the compact powder layers thereon between adjacent two of the light-emitting parts.

### BACKGROUND OF THE INVENTION

### 1. Field of the Invention

The present invention relates to a film coating method and a light-emitting device with an optical wavelength conversion layer.

### 2. Description of the Prior Art

Light-emitting diodes (LEDs) have the advantages of high luminous efficiency, low power consumption, long service life, and small component size, and have been widely used in various light-emitting devices. LEDs generally use various phosphors to produce light of different colors. In general, the phosphor is added to a resin, and the resin is stirred to make the phosphor uniformly dispersed evenly therein. Then, the phosphor-dispersed resin is mixed with a curing agent, and the light-emitting diode is coated with the mixture. However, in order to disperse the phosphor uniformly in the resin, it is difficult to increase the distribution density of the phosphor in the resin. Furthermore, when a plurality of LEDs on a substrate are coated with the resin at the same time, areas on the substrate that do not need to be coated will also be coated with the resin, which will increase the usage of the phosphor. Besides, it is difficult to apply a separate phosphor coating for each LED.

### SUMMARY OF THE INVENTION

An objective of the invention is to provide a film coating method, which can selectively coat an object with a coating material film through a mask.

A film coating method according to the invention includes the following steps of: providing an object to be coated; providing a mask, the mask having a pattern; disposing the mask above the object to expose a surface area to be coated of the object through the pattern; disposing a coating material film above the object and the mask; and making the coating material film and the object approach each other so that the coating material film forms a coating layer on the surface area through the pattern. Compared with the prior art, the thickness of the coating layer is uniform and controllable. The mask can provide selective coating to the object to be coated, and can save the usage of coating material film. In practice, the material of the coating material film that is not coated on the object to be coated can be recycled.

Another objective of the invention is to provide a light-emitting device, which has a compact optical wavelength conversion powder layer, which can improve light conversion efficiency.

A light-emitting device according to the invention includes a substrate and a plurality of light-emitting parts. The substrate has an upper surface. The plurality of light-emitting parts are separately arranged on the upper surface. The light-emitting part has a light-emitting surface. The light-emitting surface is covered by an optical wavelength conversion layer. The optical wavelength conversion layer is a compact powder layer and touches the upper surface. The upper surface has a clearance area between adjacent two of the light-emitting parts. The clearance area is not covered by the powder layers. Compared with the prior art, the optical wavelength conversion layer can provide higher light conversion efficiency, and there is no optical wavelength conversion layer on the clearance area, which can save the material of the optical wavelength conversion layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a flow chart of a film coating method according to the invention.

FIG. 2 is a flow chart of a film coating method according to a first embodiment.

FIG. 3 is a schematic diagram illustrating an object to be coated according to the first embodiment.

FIG. 4 is a schematic diagram illustrating that the object is placed into a tank according to the first embodiment.

FIG. 5 is a schematic diagram of forming a coating material film on a liquid surface by suspension.

FIG. 6 is a schematic diagram of using a temporary carrying plate to place the coating material film on the liquid surface.

FIG. 7 and FIG. 8 are schematic diagrams of making the coating material film and the object close to each other by removing the liquid.

FIG. 9 is a schematic diagram of making the coating material film and the object close to each other by lifting the object.

FIG. 10 is a schematic diagram of forming a protection layer on a coating layer after removing a mask.

FIG. 11 is a schematic diagram of retaining the mask and forming a protection layer on the coating layer.

FIG. 12 is a schematic diagram illustrating a light-emitting device that is formed after coating the object with the required coating layer.

FIG. 13 is a schematic diagram of selectively exposing a surface area to be coated of the object with a mask according to the second embodiment.

FIG. 14 is a schematic diagram of forming a protection layer on a coating layer after removing the mask.

FIG. 15 is a schematic diagram of selectively exposing another surface area to be coated of the object with another mask.

FIG. 16 is a schematic diagram of retaining the mask and forming a protection layer on the coating layer.

FIG. 17 is a schematic diagram illustrating a light-emitting device that is formed after coating the object with the required coating layers.

### DETAILED DESCRIPTION

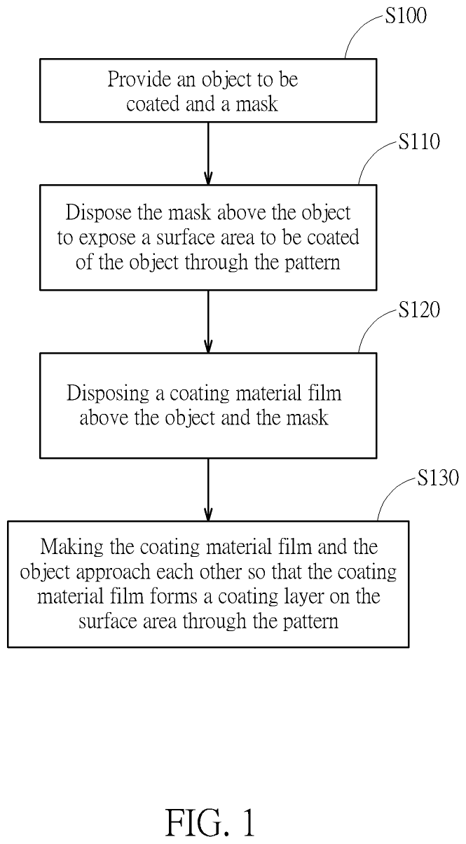

Please refer to FIG. 1. A film coating method according to the invention is used for forming a coating layer on an object to be coated. According to the film coating method, as shown by the step S100, an object to be coated and a mask are provided. The mask has a pattern. Then, as shown by the step S110, the mask is disposed above the object to expose a surface area to be coated of the object through the pattern. As shown by the step S120, a coating material film is disposed above the object and the mask. As shown by the step S130, the coating material film and the object approach each other so that the coating material film forms a coating layer on the surface area through the pattern. Thereby, the thickness of the coating layer is uniform and controllable. The mask can provide selective coating to the object to be coated, and can save the usage of coating material film.

### First Embodiment

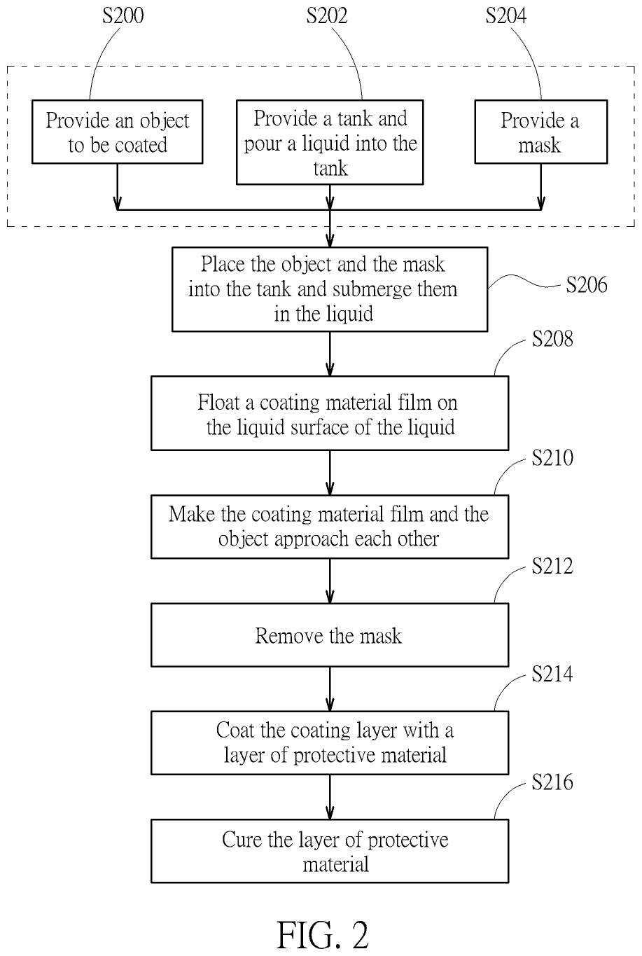

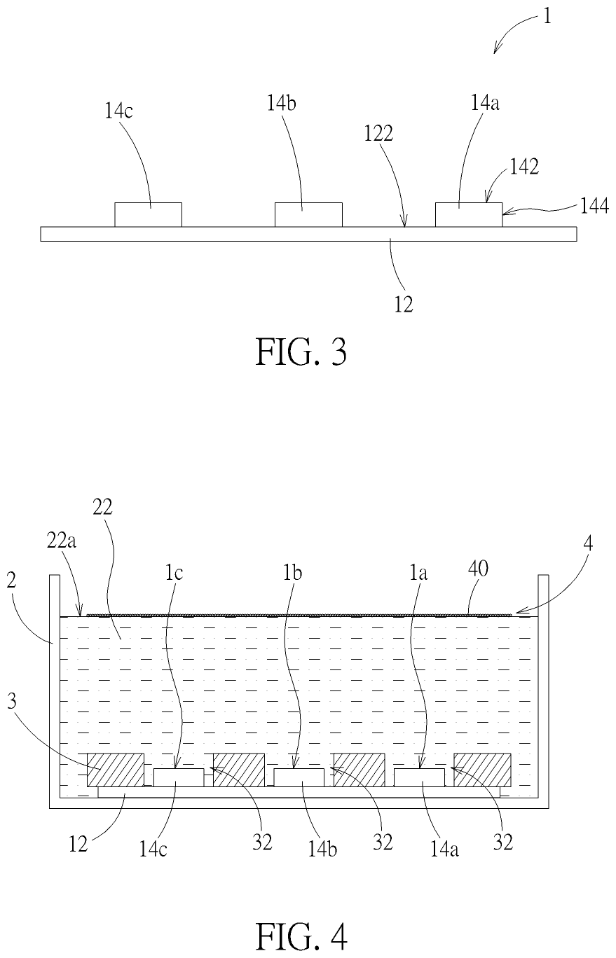

Please refer to FIG. 2 to FIG. 4. According to a first embodiment, the film coating method is used in the manufacture of a light-emitting device. In the first embodiment, as shown by the step S200, the film coating method is to provide an object 1 to be coated. As shown by FIG. 3, the object 1 includes a substrate 12 and a plurality of light-emitting parts 14a, 14b and 14c. The substrate 12 has an upper surface 122. The light-emitting parts 14a, 14b and 14c are separately arranged on the upper surface 122; that is, there are gaps between the light-emitting parts 14a, 14b and 14c. The light-emitting parts 14a, 14b and 14c may be, but are not limited to, LEDs. As shown by the step S202, the film coating method is to provide a tank 2 and pour a liquid 22 into the tank 2 (as shown by FIG. 4). As shown by the step S204, the film coating method is to provide a mask 3. As shown by FIG. 4, the mask 3 has a pattern 32 (for example, formed by three through holes corresponding to the light-emitting parts 14a, 14b and 14c). As shown by the step S206, the object 1 and the mask 3 are placed into the tank 2 to be submerged in the liquid 22 (as shown by FIG. 4). Therein, the mask 3 is disposed above the object 1 to expose the light-emitting parts 14a, 14b and 14c of the object 1 through the pattern 32. The light-emitting parts 14a, 14b and 14c have a top surface 142 and a side surface 144 which are exposed from the pattern 32. The portion of the upper surface 122 of the substrate 12 that surrounds the light-emitting parts 14a, 14b and 14c is also exposed through the pattern 32, and the other parts of the upper surface 122 are covered by the mask 3. Therein, the top surfaces 142, the side surfaces 144, and the portion of the upper surface 122 that surrounds the light-emitting parts 14a, 14b and 14c are surface areas 1a, 1b and 1c to be coated of the object 1. In other words, the light-emitting parts 14a, 14b and 14c are located within the projection of the pattern 32 on the object 1.

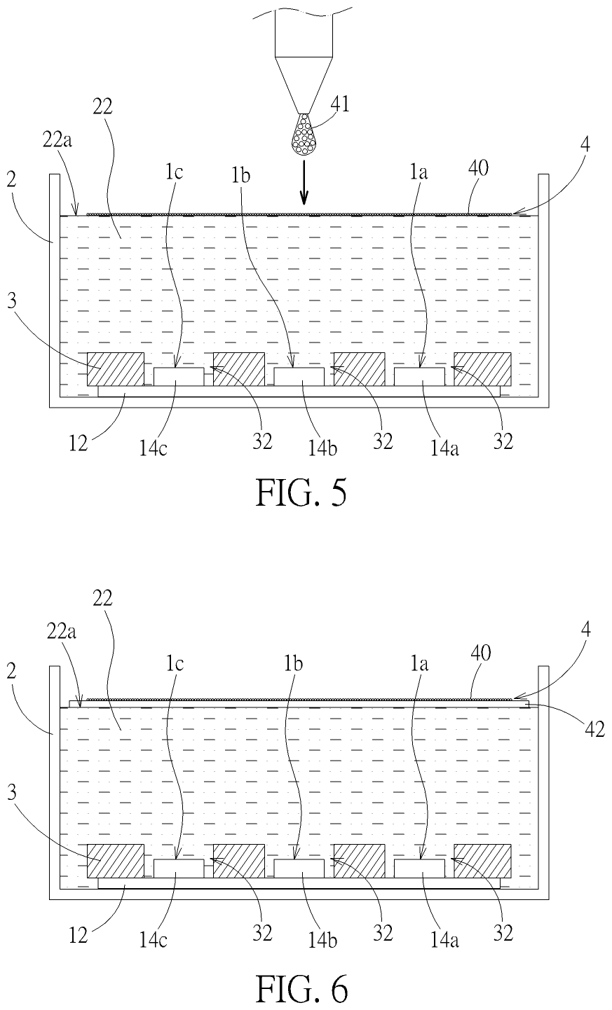

Then, as shown by the step S208, the film coating method is to float a coating material film 4 on the liquid surface 22a of the liquid 22 (as shown by FIG. 4), for achieving the disposition the coating material film 4 above the object 1 and the mask 3. Therein, the coating material film 4 includes a plurality of optical wavelength conversion particles 40 (for drawing simplification, shown in a single-layer arrangement in the figure, but it is not limited thereto in practice), which may be, but are not limited to, phosphors, quantum dots, etc. In practice, it is practicable to provide a suspension 41 first which includes a solvent and the light wavelength conversion particles 40 suspended in the solvent. As shown by FIG. 5, the suspension 41 is dropped onto the liquid surface 22a of the liquid 22 (for example, by using a dropper). Due to the surface tension of the liquid 22, the suspension 41 diffuses on the liquid surface 22a, so that the plurality of optical wavelength conversion particles 40 are distributed into a film. Therein, the solvent can be alcohols, esters, ethers or other similar organic solvents, and the liquid 22 can be water or other liquids with properties similar to water.

In FIG. 5, the optical wavelength conversion particles 40 form a thin film on the liquid surface 22a through the suspension 41, but the thin film can also be formed by other ways in practice. For example, in the step S208, the film coating method can be to provide a temporary carrying plate 42, to place the coating material film 4 on a temporary carrying plate 42, to float the temporary carrying plate 42 on the liquid surface 22a of the liquid 22 (as shown by FIG. 6), and to remove the temporary carrying plate 42 to float the coating material film 4 on the liquid surface 22a of the liquid 22 (equivalent to FIG. 4). Therein, an appropriate solvent can be selected to dissolve the temporary carrying plate 42 (for example, by spraying), so that the coating material film 4 can directly float on the liquid surface 22a of the liquid 22. The temporary carrying plate 42 can be made of any kind of water-soluble material or non-water-soluble material. The water-soluble material can be any water-soluble polymer, such as polyvinyl alcohol (PVA). PVA is solid and can be in the form of white powder, flakes or floccus. PVA contains many alcohol groups, is polar, and can form hydrogen bonds with water, so it can be dissolved in polar water. PVA is also soluble in hot hydroxyl-containing solvents such as glycerin, phenol, etc. (which can also be used as solvents), but is insoluble in general organic solvents such as methanol, benzene, acetone, and gasoline (which cannot be used as solvents).

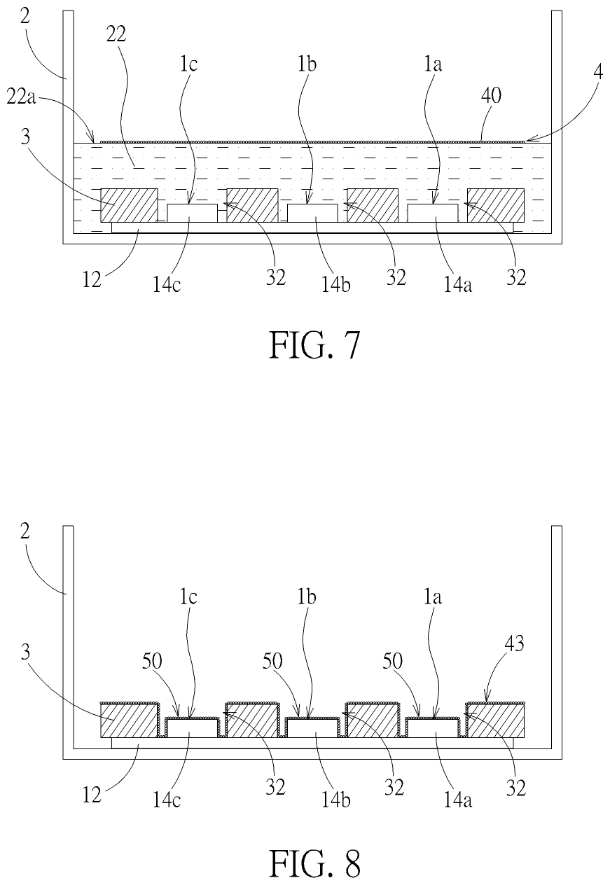

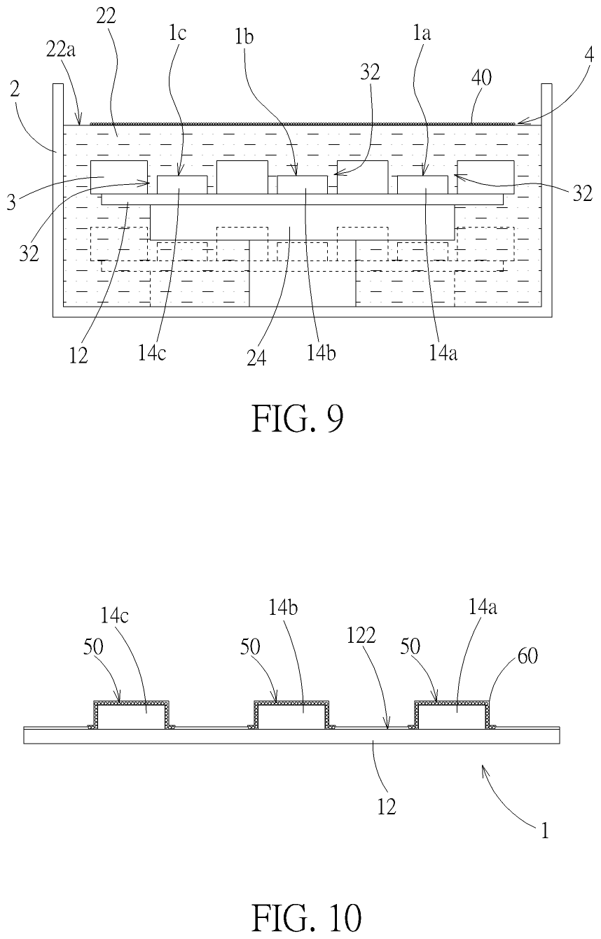

Please refer back to FIG. 2 and FIG. 4, and also refer to FIG. 7 and FIG. 8. In the first embodiment, as shown by the step S210, the film coating method is to make the coating material film 4 and the object 1 approach each other so that the coating material film 4 forms a coating layer 50 on each surface area 1a, 1b and 1c through the pattern 32. The coating material film 4 also forms a residual film 43 on the mask 3. Therein, the liquid 22 is removed (such as by controlling a valve (not shown in the figures) of the tank 2 to drain the liquid 22) so that the coating material film 4 approaches the object 1 as the liquid surface 22a drops; under the shielding effect of the mask 3, the portion of the coating material film 4 corresponding to the pattern 32 can be attached to the object 1. In practice, as shown by FIG. 9, it is practicable to lift the object 1 to make the coating material film 4 and the object 1 approach each other. Therein, the lifting of the object 1 can be achieved by a lifting device 24 disposed in the tank 2. The lifting device 24 can move up and down and is used for carry the object 1.

Please refer back to FIG. 2 and FIG. 8. In the first embodiment, the coating layer 50 is an optical wavelength conversion layer, i.e. a compact powder layer formed by the optical wavelength conversion particles 40 close to each other. The coating layer 50 does not need to be carried by an additional carrying material (such as silicon or epoxy). The optical wavelength conversion particles 40 can directly touch the surface areas 1a, 1b and 1c. The coating layer 50 covers the top surface 142 and the side surface 144, so that whether the light-emitting surface of the light-emitting part 14a, 14b and 14c is the top surface 142, the side surface 144, or the both, the light-emitting surface will be covered by the coating layer 50; thereby, the coating layer 50 can convert light emitted by the light-emitting part 14a, 14b and 14c. The compact arrangement of the optical wavelength conversion particles 40 helps to improve the light conversion efficiency.

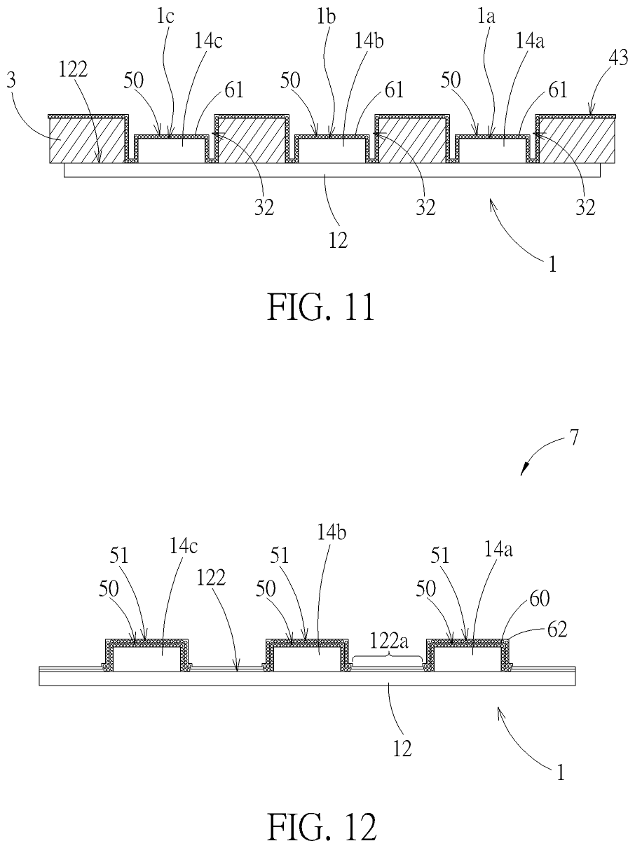

In the first embodiment, as shown by the step S212, the mask 3 is removed. As shown by the step S214, the coating layer 50 is coated with a layer of protective material. As shown by the step S216, the layer of protective material is cured (for example, by baking, lighting or other curing methods, depending on the characteristics of the layer of protective material) to form a protection layer 60, as shown by FIG. 10 (therein the same protection layer 60 covers the entire object 1, which also covers the coating layer 50). Because the mask 3 is removed first, the residual film 43 on the mask 3 can be recycled and reused. The protection layer 60 can fix the coating layer 50 to the object 1 and provide protection for the coating layer 50. In practice, inorganic glue can be used as the protection layer 60. Furthermore, in practice, it is practicable not to remove the mask 3, so that a layer of protective material coats the coating layers 50 and the residual film 43 at the same time. The layer of protective material is cured to form a protection layer 61 on each coating layer 50, as shown by FIG. 11. When the object 1 requires multilayer coating, this method helps to shorten the overall process time.

In the first embodiment, the film coating method repeats the above steps of pouring the liquid 22 into the tank 2 (as shown by the step S202), disposing the mask 3 above the object 1 (as shown by the step S206), floating another coating material film on the liquid surface 22a of the liquid 22 (as shown by the step S208), making the coating material film and the object 1 approach each other so that a coating layer 51 is formed on the protection layer 60 (as shown by the step S210), and forming a protection layer 62 on the coating layer 51 (as shown by the steps S212, S214 and S216). In this case, as shown by FIG. 12, each of the light-emitting parts 14a, 14b and 14c has the coating layers 50 and 51. Thereby, the object 1 after the above film coating can be used as a light-emitting device 7. In practice, the light-emitting parts 14a, 14b and 14c can emit blue light. The coating layer 50 and the coating layer 51 have different compositions. Therein, the coating layer 50 is an optical wavelength conversion layer of red light, and the coating layer 51 is an optical wavelength conversion layer of green light, so that the light-emitting device 7 can provide white light. Therefore, the light-emitting device 7 can be made into a full-area array type white backlight, for example, used in a backlight module of a display device. Besides, in practice, the number and composition of the coating layers on the light emitting parts 14a, 14b and 14c may be determined according to the wavelength composition of the light emitted by the light emitting parts 14a, 14b and 14c. For example, a blue LED is provided with a yellow optical wavelength conversion layer; an ultraviolet LED is provided with red, green and blue optical wavelength conversion layers.

Furthermore, in the first embodiment, the mask 3 provides the object 1 selective coating through pattern 32. Therefore, in the light-emitting device 7 in FIG. 12, the upper surface 122 of the substrate 12 has a clearance area 122a between the two adjacent light-emitting parts 14a and 14b (or the two adjacent light-emitting parts 14b and 14c). The clearance area 122a is not covered by the coating layers 50 and 51. Furthermore, although the first embodiment uses the formation of the required coating layers 50 and 51 (i.e., the optical wavelength conversion layers) on the light-emitting parts 14a, 14b and 14c as an example to illustrate the film coating method, the film coating method can also be applied to other objects in practice. For example, this object to be coated includes a substrate (e.g. printed circuit board) and an electronic component (e.g. active or passive components) on the substrate. The coating layer formed on the electronic component by the film coating method can be used to protect the electronic component, such as preventing electrostatic discharge.

In addition, in the first embodiment, the coating layers 50 and 51 on the light-emitting parts 14a, 14b and 14c are formed by the film coating method; however, in practice, the coating layer 50 on the light-emitting parts 14a, 14b and 14c may be formed by other methods, and the coating layer 51 is formed by the film coating method. In this case, the coating layer 50 is equivalent to a pre-coated layer, and the surface area to be coated with the coating layer 51 is located on the surface of the pre-coated layer. In other words, the film coating method can also apply the coating of another coating layer to an object that is coated with a pre-coated layer.

### Second Embodiment

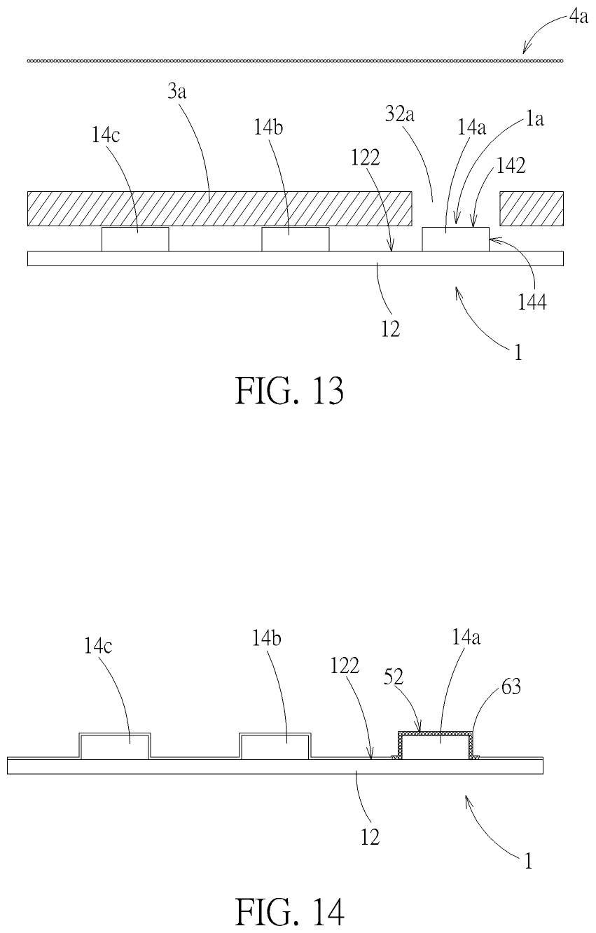

In addition, in the first embodiment, the light-emitting parts 14a, 14b and 14c are coated with the coating layers 50 and 51 of the same composition. However, in practice, it is practicable to use different masks to selectively form coating layers on the light-emitting parts 14a, 14b and 14c, and the composition of coating layers can be different. For example, in a second embodiment, the film coating method is to coat the light-emitting parts 14a and 14b with coating layers of different compositions. For simplification of description and drawing, the following mainly describes the relative arrangement of masks 3a, 3b, coating material films 4a, 4b, and the object 1 to be coated. For other descriptions of coating, please refer to the relevant descriptions of the first embodiment and variations thereof in the foregoing, which will not be repeated in addition. As shown by FIG. 13, in the second embodiment, the film coating method is to dispose the mask 3a above the object 1. The mask 3a covers the light-emitting parts 14b and 14c but exposes the surface area 1a through a pattern 32a of the mask 3a. The coating material film 4a is disposed above the object 1 and the mask 3a. After the coating material film 4a forms a coating layer 52 on the surface area 1a through the pattern 32a, the mask 3a is removed and then a layer of protective material is coated on the coating layer 52. The layer of protective material is cured to form a protection layer 63, as shown by FIG. 14.

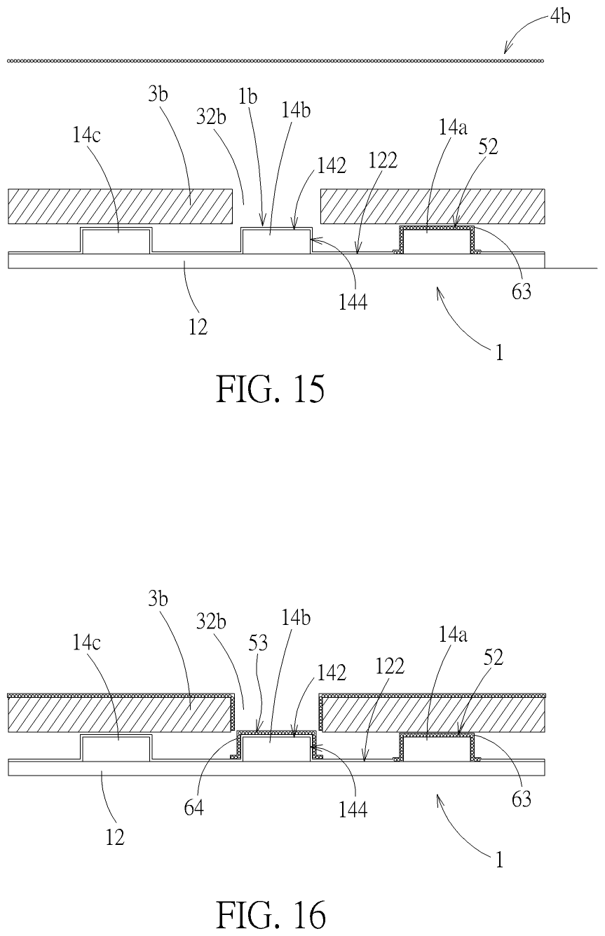

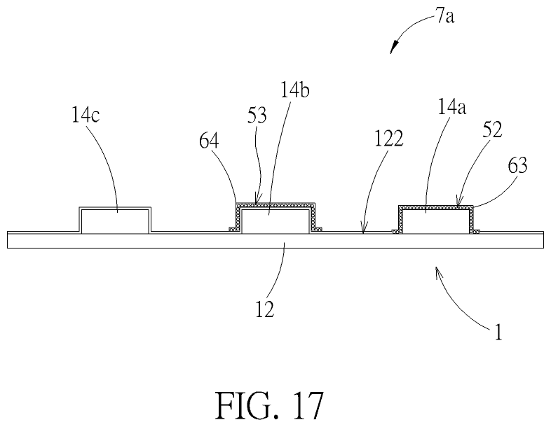

Then, as shown by FIG. 15, the mask 3b is disposed above the object 1. The mask 3b covers the light-emitting part 14a (and the protection layer 63 thereon) and the light-emitting part 14c, but exposes the surface area 1b through a pattern 32b of the mask 3b. The coating material film 4b is disposed above the object 1 and the mask 3b. After the coating material film 4b forms a coating layer 53 on the surface area 1b through the pattern 32b, before the mask 3b is removed, a layer of protective material is coated on the coating layer 53. The layer of protective material is cured to form a protection layer 64, as shown by FIG. 16. Thereby, the object 1 after the above film coating can be used as a light-emitting device 7a used in a display device, as shown by FIG. 17. In the second embodiment, the light-emitting part 14c can emit blue light. The coating layer 52 is a red optical wavelength conversion layer, and the coating layer 53 is a green optical wavelength conversion layer, so that the light-emitting device 7a can provide red light, green light, and blue light, and their mixing can produce a variety of colored light or white light. Therefore, the light-emitting device 7a can be made into a full-area RGB array type displaying panel. In practice, the composition of the coating layers on the light-emitting parts 14a, 14b and 14c may be determined according to the wavelength composition of the light emitted by the light emitting parts 14a, 14b and 14c, which will not be described in addition. Furthermore, in practice, the protection layers 63 and 64 may contain blue-absorbing materials, which can reduce the color shift of red and green light.

In addition, in the second embodiment, the coating layers 52 and 53 on the light-emitting parts 14a and 14b are formed by the film coating method; however, in practice, the coating layer 52 on the light-emitting part 14a may be formed by other methods, and the coating layer 53 is formed by the film coating method. In this case, the coating layer 52 is equivalent to a pre-coated layer, and the mask 3b covers the pre-coated layer when forming the coating layer 53. In other words, the film coating method can also apply the coating of another coating layer to an object that is coated with a pre-coated layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A film coating method, comprising the following steps of:
(a) providing an object to be coated;
(b) providing a mask, the mask having a pattern;
(c) disposing the mask above the object to expose a surface area to be coated of the object through the pattern;
(d) disposing a coating material film above the object and the mask; and
(e) making the coating material film and the object approach each other so that the coating material film forms a coating layer on the surface area through the pattern.

2. The film coating method according to claim 1, wherein before the step (c), the film coating method comprises the following steps of:
providing a tank;
pouring a liquid into the tank; and
submerging the object into the liquid; and
in the step (d), the coating material film is disposed above the object and the mask by floating the coating material film on the liquid surface of the liquid.

3. The film coating method according to claim 2, wherein in the step (e), the coating material film and the object approach each other by removing the liquid from the tank or raising the object.

4. The film coating method according to claim 2, wherein in the step (d), the coating material film floats on the liquid surface of the liquid by the following steps of:
providing a temporary carrying plate;
placing the coating material film on the temporary carrying plate;
floating the temporary carrying plate on the liquid surface of the liquid; and
removing the temporary carrying plate to float the coating material film on the liquid surface of the liquid.

5. The film coating method according to claim 1, wherein the object has a pre-coated layer, and the surface area is located on a surface of the pre-coated layer.

6. The film coating method according to claim 1, wherein the coating layer is a compact powder layer.

7. The film coating method according to claim 1, wherein after the coating layer is formed, the film coating method comprises the following steps of:
removing the mask; and
forming a protection layer on the coating layer to cover the coating layer.

8. The film coating method according to claim 1, wherein in the step (c), the object has a pre-coated layer, and the mask shields the pre-coated layer.

9. The film coating method according to claim 1, wherein the object comprises a substrate and an electronic component on the substrate, and in the step (c), the electronic component is located within a projection of the pattern on the object.

10. The film coating method according to claim 9, wherein the electronic component is a light-emitting part, the surface area comprises a light-emitting surface of the light-emitting part, and the coating layer is an optical wavelength conversion layer.

11. The film coating method according to claim 10, wherein the coating layer is a compact powder layer comprising a plurality of optical wavelength conversion particles.

12. The film coating method according to claim 10, wherein the light-emitting surface comprises a top surface and a side surface.

13. Alight-emitting device, comprising:
a substrate, having an upper surface; and
a plurality of light-emitting parts, separately arranged on the upper surface, the light-emitting part having a light-emitting surface covered by an optical wavelength conversion layer, the optical wavelength conversion layer being a compact powder layer and touching the upper surface, the upper surface having a clearance area between adjacent two of the light-emitting parts, the clearance area being not covered by the powder layers.

14. The light-emitting device according to claim 13, wherein the optical wavelength conversion layer is covered by a protection layer.

15. The light-emitting device according to claim 14, wherein the protection layer is covered by another optical wavelength conversion layer.

16. The light-emitting device according to claim 15, wherein the two optical wavelength conversion layers on the light-emitting part have different compositions.

17. The light-emitting device according to claim 13, wherein the compositions of the optical wavelength conversion layers on adjacent two of the light-emitting parts are different.
